(19) United States
(12) Patent Application Publication
(10) Pub. No.: US 2021/0226075 A1
(43) Pub. Date: Jul. 22, 2021

(54) Silicon-Based Solar Cell Panel

(71) Applicant: Minyan Huang, Haimen (CN)

(72) Inventor: Minyan Huang, Haimen (CN)

(21) Appl. No.: 16/314,129

(22) PCT Filed: Oct. 24, 2018
(86) PCT No.: PCT/CN2018/111693

§ 371 Date: Dec. 28, 2018

(30) Foreign Application Priority Data
Apr. 25, 2018 (CN) 201810381521.4

(51) Int. Cl. H01L 31/052; H01L 31/048; H01L 31/049

(52) U.S. Cl. CPC H01L 31/052; H01L 31/049; H01L 31/0481

(57) ABSTRACT

The present application provides a silicon-based solar cell panel, wherein the silicon-based solar cell panel comprises a solar cell back plate, a first thermally conductive encapsulant adhesive layer, a second encapsulant adhesive layer, a plurality of silicon-based solar cell sheets, a third encapsulant adhesive layer and a tempered glass plate, wherein a first columnar groove is formed in a plurality of resin layers on the upper surface of a first metal plate, each of the first columnar grooves is embedded with a thermally conductive elastic pillar, a plurality of columnar protrusions arranged in an array are provided on the lower surface of the first metal plate, a portion of the columnar protrusions is embedded in the second columnar groove of the second metal plate, a rubber buffer layer is provided between the first metal plate and the second metal plate, and the lower surface of the second metal plate is formed with a groove in which a metal block is embedded. The cell panel of the present invention has excellent heat dissipation performance, seismic resistance and moisture barrier performance.

### TECHNICAL FIELD

The present application relates to the technical field of solar cells, and in particular to a silicon-based solar cell panel.

### BACKGROUND

With the development and advancement of science and technology, the demand for energy has also increased dramatically. The commonly used energy sources come from fossil energy oil, coal and natural gas. Since petrochemical energy has a limited total reserve and is non-renewable energy, the world is facing a severe energy situation, making people's exploration of emerging renewable energy such as wind, geothermal and solar energy increasingly urgent. Among them, solar energy has gradually received widespread attention as an inexhaustible green renewable energy, and solar cell related technologies are also booming. Among the existing types of solar cells, silicon-based solar cells have been widely used due to high efficiency and mature manufacturing processes. The existing silicon-based solar cell assembly typically comprises a glass cover plate, a first EVA adhesive layer, a solar cell sheet layer, a second EVA adhesive layer, and a solar cell back plate. The existing solar cell back plate has a TPT back plate and a TPE back plate. The TPT back plate is formed in such a way that a PVF layer is bonded on both sides of the PET layer after both sides of the PET layer having a thickness of 300 μm are coated with an adhesive, and the TPT back plate has excellent weather resistance; the TPE back plate is formed in such a way that a PVF layer is bonded on the lower surface of the PET layer and a PE layer or the EVA layer is bonded on the upper surface of the PET layer after both sides of the PET layer having a thickness of 300 μm are coated with an adhesive, and the TPE back plate also has excellent weather resistance. However, the existing solar cell backplane has poor seismic resistance, sealing performance and thermal conductivity, so that the corresponding silicon-based solar assembly is be easily damaged, and the output power easily decreases during long-term use.

### SUMMARY

The purpose of the present application is to overcome the deficiencies of the prior art described above and to provide a silicon-based solar cell panel.

To achieve the above object, the present application proposes a silicon-based solar cell panel, wherein the silicon-based solar cell panel comprises:
a solar cell back plate, wherein the solar cell back plate comprises a first metal plate, a first polyester film layer is bonded to the upper surface of the first metal plate, a polyimide film is bonded to the upper surface of the first polyester film layer, a first polyolefin bonding layer is provided on the upper surface of the polyimide film, a plurality of first columnar grooves are arranged in an array, the first columnar grooves penetrate through the first polyolefin bonding layer, the polyimide film and the first polyester film layer and expose the upper surface of the first metal plate, each of the first columnar grooves is embedded with a thermally conductive elastic pillar, the upper end portion of the thermally conductive elastic pillar is exposed to the first polyolefin bonding layer, the bottom surface of the thermally conductive elastic pillar is in contact with the first metal plate, and a plurality of columnar protrusions arranged in an array are provided on the lower surface of the first metal plate;
a rubber buffer layer, wherein the rubber buffer layer covers the lower surface of the first metal plate, and a portion of each of the columnar protrusions are exposed to the rubber buffer layer;
a second metal plate, wherein a plurality of second columnar grooves distributed in an array are provided on the upper surface of the second metal plate, the second columnar grooves are in one-to-one correspondence with the columnar protrusions, the portion of each of the columnar protrusions is embedded in the corresponding second columnar groove, a second polyester film layer is bonded to the lower surface of the second metal plate, a polypropylene layer is bonded to the lower surface of the second polyester film layer, a fluorine-containing resin layer is bonded to the lower surface of the polypropylene layer, a plurality of grooves are arranged in an array, the grooves penetrate through the fluorine-containing resin layer, the polypropylene layer, and the second polyester film layer and expose the lower surface of the second metal plate, each of the grooves is embedded with a metal block, the top surface of the metal block is in contact with the lower surface of the second metal plate, and the lower end portion of the metal block is exposed to the fluorine-containing resin layer;
a first thermally conductive encapsulant adhesive layer, wherein the first thermally conductive encapsulant adhesive layer covers the solar cell back plate, the upper end portion of the thermally conductive elastic pillar exposed to the first polyolefin bonding layer is embedded in the first thermally conductive encapsulant adhesive layer;
a second encapsulant adhesive layer, wherein the second encapsulant adhesive layer covers the first thermally conductive encapsulant adhesive layer;
a plurality of silicon-based solar cell sheets provided on the second encapsulant adhesive layer;
a third encapsulant adhesive layer, wherein the third encapsulant adhesive layer covers the silicon-based solar cell sheets; and
a tempered glass plate, wherein the tempered glass plate is provided above the third encapsulant adhesive layer.

Preferably, the first metal plate and the second metal plate are made of one of aluminum, copper, stainless steel, and aluminum-magnesium alloy, the first polyester film layer has a thickness of 2-4 mm, the polyimide film has a thickness of 1-1.5 mm, and the first polyolefin bonding layer has a thickness of 100-150 μm.

Preferably, the thermally conductive elastic pillar comprises a metal copper core, a silicone rubber layer is provided on the side surface of the metal copper core, a second polyolefin bonding layer is provided on the surface of the silicone rubber layer, the metal copper core has a diameter of 5-10 mm, the silicone rubber layer has a thickness of 5-10 mm, and the second polyolefin bonding layer has a thickness of 50-100 μm.

Preferably, the columnar protrusions have a diameter of 2-5 mm, the adjacent columnar protrusions have a pitch of 4-8 mm, the columnar protrusions have a height of 0.4-0.8 mm, the rubber buffer layer has a thickness 300-700 pm, and the portion of the columnar protrusions exposed to the rubber buffer layer has a height of 50-100 μm.

Preferably, the second polyester film layer has a thickness of 1-3 mm, the polypropylene layer has a thickness of 0.5-1 mm, the fluorine-containing resin layer has a thickness of 100-200 μm, the metal block is made of aluminum or copper, and the lower end portion of the metal block exposed to the fluorine-containing resin layer has a length of 1-2 mm.

Preferably, the first thermally conductive encapsulant adhesive layer comprises a polyolefin resin and a thermally conductive nanoparticle, the thermally conductive nanoparticle is one of aluminium oxide, aluminum nitride, boron nitride, silicon nitride and magnesium oxide, the thermally conductive nanoparticle has a particle diameter of 100-200 nm, and the second encapsulant adhesive layer and the third encapsulant adhesive layer are made of polyolefin.

Preferably, the first thermally conductive encapsulant adhesive layer has a thickness of 400-500 μm, the second encapsulant adhesive layer has a thickness of 50-100 μm, the third encapsulant adhesive layer has a thickness of 200-300 μm, and the upper end portion of the thermally conductive elastic pillar embedded in the first thermally conductive encapsulant adhesive layer has a length of 200-400 μm.

Preferably, the fluorine-containing resin layer is made of polytetrafluoroethylene, polychlorotrifluoroethylene, polyvinylidene fluoride, polyvinyl fluoride, an ethylene-chlorotrifluoroethylene copolymer or an ethylene-tetrafluoroethylene copolymer.

Compared with the prior art, the beneficial effects of the present application are as follows.

In the silicon-based solar cell panel of the present application, a first columnar groove is formed in the multilayer resin layer on the surface of the first metal plate, and a thermally conductive elastic pillar is embedded in each of the first columnar grooves so that in the process of forming a thick back plate, the plurality of thermally conductive elastic pillars form a plurality of heat dissipation paths, respectively, the heat generated by the solar cell sheet can be quickly conducted to the first metal plate, a plurality of columnar protrusions arranged in an array are provided on the lower surface of the first metal plate, a portion of the columnar protrusions is embedded in the second columnar groove of the second metal plate, a rubber buffer layer is provided between the first metal plate and the second metal plate which is convenient for heat transfer so that the solar cell back plate has excellent seismic resistance. A second polyester film layer, a polypropylene layer, and a fluorine-containing resin layer are provided on the lower surface of the second metal plate, and a groove is formed in which the metal column is embedded so that while the entire solar cell back plate has excellent thermal conductivity formation, the presence of the first and second metal sheets can effectively prevent moisture from intruding into the silicon-based solar cell panel. By optimizing the structure of the thermally conductive elastic pillar, the thermally conductive elastic pillar comprises a metal copper core, a silicone rubber layer and a second polyolefin bonding layer, so that the thermally conductive elastic pillar has excellent thermal conductivity and also has excellent cushioning and shock absorbing performance. The double-shock absorbing structure is designed so that the solar cell sheet will not be damaged and broken even if the monocrystalline silicon cell assembly collides. The upper end of the thermally conductive elastic pillar is embedded in the first thermally conductive encapsulant adhesive layer, and the area of the thermally conductive elastic pillar and the first thermally conductive encapsulation layer is increased, thereby further improving the stability and thermal conductivity of the monocrystalline silicon cell assembly. A polyolefin bonding layer is provided on the surface of the encapsulant back plate, and an ultra-thin second encapsulant adhesive layer is provided between the first thermally conductive encapsulant adhesive layer and the silicon-based solar cell sheet layer, so that the entire cell plate is more easily bonded into one body. Compared with the existing cell plate, by optimizing the specific structure of the silicon-based solar cell panel of the present application and the specific size of each layer, the silicon-based solar cell panel of the present application is thick overall, and has excellent heat dissipation performance, seismic resistance and moisture barrier performance, ensuring that the photoelectric conversion efficiency of the silicon-based solar cell panel is not attenuated, and ensuring that the output power thereof is stable and suitable for long-term use.

### BRIEF DESCRIPTION OF THE DRAWINGS

FIG. 1 is a schematic structural view of a silicon-based solar cell panel according to the present application.

FIG. 2 is a top view of a solar cell back plate according to the present application.

FIG. 3 is a bottom view of a first metal plate according to the present application.

FIG. 4 is a bottom view of a solar cell back plate according to the present application.

FIG. 5 is a schematic structural view of a bottom surface of a thermally conductive elastic pillar according to the present application.

### DESCRIPTION OF THE EMBODIMENTS

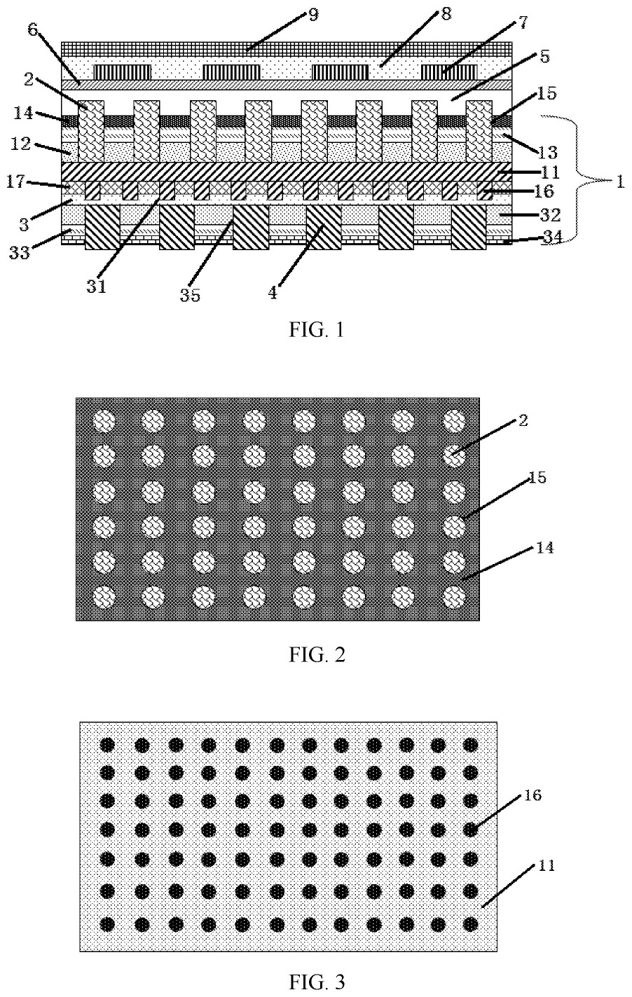

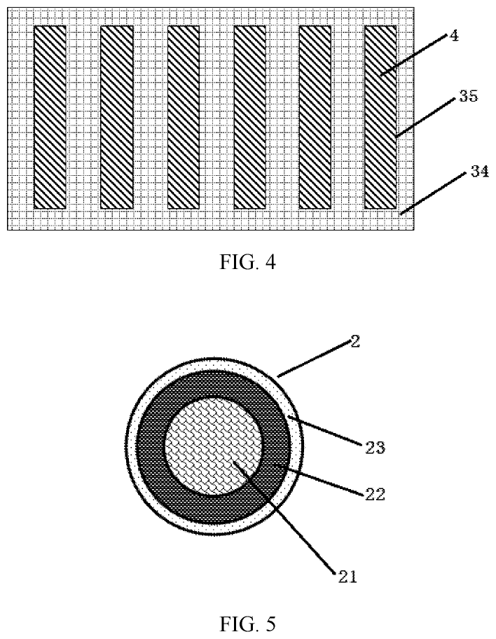

As shown in FIGS. 1-5, the present application provides a silicon-based solar cell panel, comprising: a solar cell back plate 1, wherein the solar cell back plate 1 comprises a first metal plate 11, a first polyester film layer 12 is bonded to the upper surface of the first metal plate 11, a polyimide film 13 is bonded to the upper surface of the first polyester film layer 12, a first polyolefin bonding layer 14 is provided on the upper surface of the polyimide film 13, a plurality of first columnar grooves 15 are arranged in an array, the first columnar grooves 15 penetrate through the first polyolefin bonding layer 14, the polyimide film 13 and the first polyester film layer 12 and expose the upper surface of the first metal plate 11, each of the first columnar grooves 15 is embedded with a thermally conductive elastic pillar 2, the upper end portion of the thermally conductive elastic pillar 2 is exposed to the first polyolefin bonding layer 14, the bottom surface of the thermally conductive elastic pillar 2 is in contact with the first metal plate 11, and a plurality of columnar protrusions 16 arranged in an array are provided on the lower surface of the first metal plate 11; a rubber buffer layer 17, wherein the rubber buffer layer 17 covers the lower surface of the first metal plate 11, and a portion of each of the columnar protrusions 16 are exposed to the rubber buffer layer 17;
a second metal plate 3, wherein a plurality of second columnar grooves 31 distributed in an array are provided on the upper surface of the second metal plate 3, the second columnar grooves 31 are in one-to-one correspondence with the columnar protrusions 16, the portion of each of the columnar protrusions 16 is embedded in the corresponding second columnar groove 31, a second polyester film layer 32 is bonded to the lower surface of the second metal plate 3, a polypropylene layer 33 is bonded to the lower surface of the second polyester film layer 32, a fluorine-containing resin layer 34 is bonded to the lower surface of the polypropylene layer 33, a plurality of grooves 35 are arranged in an array, the grooves 35 penetrate through the fluorine-containing resin layer 34, the polypropylene layer 33, and the second polyester film layer 32 and expose the lower surface of the second metal plate 3, each of the grooves 35 is embedded with a metal block 4, the top surface of the metal block 4 is in contact with the lower surface of the second metal plate 3, and the lower end portion of the metal block 4 is exposed to the fluorine-containing resin layer 34;
a first thermally conductive encapsulant adhesive layer 5, wherein the first thermally conductive encapsulant adhesive layer 5 covers the solar cell back plate 1, the upper end portion of the thermally conductive elastic pillar 2 exposed to the first polyolefin bonding layer 14 is embedded in the first thermally conductive encapsulant adhesive layer 5; a second encapsulant adhesive layer 6, wherein the second encapsulant adhesive layer 6 covers the first thermally conductive encapsulant adhesive layer 5; a plurality of silicon-based solar cell sheets 7 provided on the second encapsulant adhesive layer 6; a third encapsulant adhesive layer 8, wherein the third encapsulant adhesive layer 8 covers the silicon-based solar cell sheets 7; and a tempered glass plate 9, wherein the tempered glass plate 9 is provided above the third encapsulant adhesive layer 8.

Preferably, the first metal plate 11 and the second metal plate 3 are made of one of aluminum, copper, stainless steel, and aluminum-magnesium alloy, the first polyester film layer 12 has a thickness of 2-4 mm, the polyimide film 13 has a thickness of 1-1.5 mm, and the first polyolefin bonding layer 14 has a thickness of 100-150 μm.

Preferably, the thermally conductive elastic pillar 2 comprises a metal copper core 21, a silicone rubber layer 22 is provided on the side surface of the metal copper core 21, a second polyolefin bonding layer 23 is provided on the surface of the silicone rubber layer 22, the metal copper core 21 has a diameter of 5-10 mm, the silicone rubber layer 22 has a thickness of 5-10 mm, and the second polyolefin bonding layer 23 has a thickness of 50-100 μm.

Preferably, the columnar protrusions 16 have a diameter of 2-5 mm, the adjacent columnar protrusions 16 have a pitch of 4-8 mm, the columnar protrusions 16 have a height of 0.4-0.8 mm, the rubber buffer layer 17 has a thickness 300-700 μm, and the portion of the columnar protrusions 16 exposed to the rubber buffer layer 17 has a height of 50-100 μm.

Preferably, the second polyester film layer 32 has a thickness of 1-3 mm, the polypropylene layer 33 has a thickness of 0.5-1 mm, the fluorine-containing resin layer 34 has a thickness of 100-200 μm, the metal block 4 is made of aluminum or copper, and the lower end portion of the metal block 4 exposed to the fluorine-containing resin layer 34 has a length of 1-2 mm.

Preferably, the first thermally conductive encapsulant adhesive layer 5 comprises a polyolefin resin and a thermally conductive nanoparticle, the thermally conductive nanoparticle is one of aluminium oxide, aluminum nitride, boron nitride, silicon nitride and magnesium oxide, the thermally conductive nanoparticle has a particle diameter of 100-200 nm, and the second encapsulant adhesive layer 6 and the third encapsulant adhesive layer 8 are made of polyolefin.

Preferably, the first thermally conductive encapsulant adhesive layer 5 has a thickness of 400-500 μm, the second encapsulant adhesive layer 6 has a thickness of 50-100 μm, the third encapsulant adhesive layer 8 has a thickness of 200-300 μm, and the upper end portion of the thermally conductive elastic pillar 2 embedded in the first thermally conductive encapsulant adhesive layer 5 has a length of 200-400 μm.

Preferably, the fluorine-containing resin layer 34 is made of polytetrafluoroethylene, polychlorotrifluoroethylene, polyvinylidene fluoride, polyvinyl fluoride, an ethylene-chlorotrifluoroethylene copolymer or an ethylene-tetrafluoroethylene copolymer.

### Embodiment 1

As shown in FIGS. 1-5, the present application provides a silicon-based solar cell panel, wherein the silicon-based solar cell panel comprises: a solar cell back plate 1, wherein the solar cell back plate 1 comprises a first metal plate 11, a first polyester film layer 12 is bonded to the upper surface of the first metal plate 11, a polyimide film 13 is bonded to the upper surface of the first polyester film layer 12, a first polyolefin bonding layer 14 is provided on the upper surface of the polyimide film 13, a plurality of first columnar grooves 15 are arranged in an array, the first columnar grooves 15 penetrate through the first polyolefin bonding layer 14, the polyimide film 13 and the first polyester film layer 12 and expose the upper surface of the first metal plate 11, each of the first columnar grooves 15 is embedded with a thermally conductive elastic pillar 2, the upper end portion of the thermally conductive elastic pillar 2 is exposed to the first polyolefin bonding layer 14, the bottom surface of the thermally conductive elastic pillar 2 is in contact with the first metal plate 11, and a plurality of columnar protrusions 16 arranged in an array are provided on the lower surface of the first metal plate 11; a rubber buffer layer 17, wherein the rubber buffer layer 17 covers the lower surface of the first metal plate 11, and a portion of each of the columnar protrusions 16 are exposed to the rubber buffer layer 17;
a second metal plate 3, wherein a plurality of second columnar grooves 31 distributed in an array are provided on the upper surface of the second metal plate 3, the second columnar grooves 31 are in one-to-one correspondence with the columnar protrusions 16, the portion of each of the columnar protrusions 16 is embedded in the corresponding second columnar groove 31, a second polyester film layer 32 is bonded to the lower surface of the second metal plate 3, a polypropylene layer 33 is bonded to the lower surface of the second polyester film layer 32, a fluorine-containing resin layer 34 is bonded to the lower surface of the polypropylene layer 33, a plurality of grooves 35 are arranged in an array, the grooves 35 penetrate through the fluorine-containing resin layer 34, the polypropylene layer 33, and the second polyester film layer 32 and expose the lower surface of the second metal plate 3, each of the grooves 35 is embedded with a metal block 4, the top surface of the metal block 4 is in contact with the lower surface of the second metal plate 3, and the lower end portion of the metal block 4 is exposed to the fluorine-containing resin layer 34;
a first thermally conductive encapsulant adhesive layer 5, wherein the first thermally conductive encapsulant adhesive layer 5 covers the solar cell back plate 1, the upper end portion of the thermally conductive elastic pillar 2 exposed to the first polyolefin bonding layer 14 is embedded in the first thermally conductive encapsulant adhesive layer 5; a second encapsulant adhesive layer 6, wherein the second encapsulant adhesive layer 6 covers the first thermally conductive encapsulant adhesive layer 5; a plurality of silicon-based solar cell sheets 7 provided on the second encapsulant adhesive layer 6; a third encapsulant adhesive layer 8, wherein the third encapsulant adhesive layer 8 covers the silicon-based solar cell sheets 7; and a tempered glass plate 9, wherein the tempered glass plate 9 is provided above the third encapsulant adhesive layer 8.

The first metal plate 11 and the second metal plate 3 are made of aluminum, the first polyester film layer 12 has a thickness of 3 mm, the polyimide film 13 has a thickness of 1.2 mm, and the first polyolefin bonding layer 14 has a thickness of 120 μm. The thermally conductive elastic pillar 2 comprises a metal copper core 21, a silicone rubber layer 22 is provided on the side surface of the metal copper core 21, a second polyolefin bonding layer 23 is provided on the surface of the silicone rubber layer 22, the metal copper core 21 has a diameter of 7 mm, the silicone rubber layer 22 has a thickness of 7 mm, and the second polyolefin bonding layer 23 has a thickness of 80 μm. The columnar protrusions 16 have a diameter of 4 mm, the adjacent columnar protrusions 16 have a pitch of 6 mm, the columnar protrusions 16 have a height of 0.6 mm, the rubber buffer layer 17 has a thickness 500 μm, and the portion of the columnar protrusions 16 exposed to the rubber buffer layer 17 has a height of 100 μm.

The second polyester film layer 32 has a thickness of 2 mm, the polypropylene layer 33 has a thickness of 0.8 mm, the fluorine-containing resin layer 34 has a thickness of 150 μm, the metal block 4 is made of aluminum, and the lower end portion of the metal block 4 exposed to the fluorine-containing resin layer 34 has a length of 1.5 mm. The first thermally conductive encapsulant adhesive layer 5 comprises a polyolefin resin and a thermally conductive nanoparticle, the thermally conductive nanoparticle is aluminium oxide, the thermally conductive nanoparticle has a particle diameter of 150 nm, and the second encapsulant adhesive layer 6 and the third encapsulant adhesive layer 8 are made of polyolefin. The first thermally conductive encapsulant adhesive layer 5 has a thickness of 450 μm, the second encapsulant adhesive layer 6 has a thickness of 90 μm, the third encapsulant adhesive layer 8 has a thickness of 220 μm, and the upper end portion of the thermally conductive elastic pillar 2 embedded in the first thermally conductive encapsulant adhesive layer 5 has a length of 350 μm. The fluorine-containing resin layer 34 is made of polytetrafluoroethylene.

### Embodiment 2

This embodiment provides another silicon-based solar cell panel, which is different from Embodiment 1 in that the first metal plate 11 and the second metal plate 3 are made of copper, the first polyester film layer 12 has a thickness of 4 mm, the polyimide film 13 has a thickness of 1 mm, and the first polyolefin bonding layer 14 has a thickness of 150 μm. The metal copper core 21 has a diameter of 10 mm, the silicone rubber layer 22 has a thickness of 10 mm, and the second polyolefin bonding layer 23 has a thickness of 100 μm. The columnar protrusions 16 have a diameter of 5 mm, the adjacent columnar protrusions 16 have a pitch of 8 mm, the columnar protrusions 16 have a height of 0.7 mm, the rubber buffer layer 17 has a thickness 630 μm, and the portion of the columnar protrusions 16 exposed to the rubber buffer layer 17 has a height of 70 μm.

The second polyester film layer 32 has a thickness of 1 mm, the polypropylene layer 33 has a thickness of 1 mm, the fluorine-containing resin layer 34 has a thickness of 200 μm, the metal block 4 is made of copper, and the lower end portion of the metal block 4 exposed to the fluorine-containing resin layer 34 has a length of 2 mm. The thermally conductive nanoparticle in the first thermally conductive encapsulant adhesive layer 5 is magnesium oxide, the thermally conductive nanoparticle has a particle diameter of 200 nm, the first thermally conductive encapsulant adhesive layer 5 has a thickness of 500 μm, the second encapsulant adhesive layer 6 has a thickness of 100 μm, the third encapsulant adhesive layer 8 has a thickness of 200 μm, and the upper end portion of the thermally conductive elastic pillar 2 embedded in the first thermally conductive encapsulant adhesive layer 5 has a length of 400 μm. The fluorine-containing resin layer 34 is made of polyvinylidene fluoride.

### Embodiment 3

This embodiment provides another silicon-based solar cell panel, which is different from Embodiment 1 in that the first metal plate 11 and the second metal plate 3 are made of aluminum-magnesium alloy, the first polyester film layer 12 has a thickness of 2 mm, the polyimide film 13 has a thickness of 1.5 mm, and the first polyolefin bonding layer 14 has a thickness of 100 μm. The metal copper core 21 has a diameter of 5 mm, the silicone rubber layer 22 has a thickness of 5 mm, and the second polyolefin bonding layer 23 has a thickness of 50 μm. The columnar protrusions 16 have a diameter of 2 mm, the adjacent columnar protrusions 16 have a pitch of 4 mm, the columnar protrusions 16 have a height of 0.4 mm, the rubber buffer layer 17 has a thickness 350 μm, and the portion of the columnar protrusions 16 exposed to the rubber buffer layer 17 has a height of 50 μm.

The second polyester film layer 32 has a thickness of 3 mm, the polypropylene layer 33 has a thickness of 0.5 mm, the fluorine-containing resin layer 34 has a thickness of 100 μm, the metal block 4 is made of copper, and the lower end portion of the metal block 4 exposed to the fluorine-containing resin layer 34 has a length of 1 mm. The thermally conductive nanoparticle in the first thermally conductive encapsulant adhesive layer 5 is silicon nitride, the thermally conductive nanoparticle has a particle diameter of 100 nm, the first thermally conductive encapsulant adhesive layer 5 has a thickness of 400 μm, the second encapsulant adhesive layer 6 has a thickness of 50 μm, the third encapsulant adhesive layer 8 has a thickness of 300 μm, and the upper end portion of the thermally conductive elastic pillar 2 embedded in the first thermally conductive encapsulant adhesive layer 5 has a length of 250 μm. The fluorine-containing resin layer 34 is made of an ethylene-tetrafluoroethylene copolymer.

The above is a preferred embodiment of the present application, and it should be noted that those skilled in the art can also make several improvements and modifications which are regarded to be within the scope of protection of the present application without departing from the principles of the present application.

What is claimed is:

1. A silicon-based solar cell panel, wherein the silicon-based solar cell panel comprises:
a solar cell back plate, wherein the solar cell back plate comprises a first metal plate, a first polyester film layer is bonded to the upper surface of the first metal plate, a polyimide film is bonded to the upper surface of the first polyester film layer, a first polyolefin bonding layer is provided on the upper surface of the polyimide film, a plurality of first columnar grooves are arranged in an array, the first columnar grooves penetrate through the first polyolefin bonding layer, the polyimide film and the first polyester film layer and expose the upper surface of the first metal plate, each of the first columnar grooves is embedded with a thermally conductive elastic pillar, the upper end portion of the thermally conductive elastic pillar is exposed to the first polyolefin bonding layer, the bottom surface of the thermally conductive elastic pillar is in contact with the first metal plate, and a plurality of columnar protrusions arranged in an array are provided on the lower surface of the first metal plate;
a rubber buffer layer, wherein the rubber buffer layer covers the lower surface of the first metal plate, and a portion of each of the columnar protrusions are exposed to the rubber buffer layer;
a second metal plate, wherein a plurality of second columnar grooves distributed in an array are provided on the upper surface of the second metal plate, the second columnar grooves are in one-to-one correspondence with the columnar protrusions, the portion of each of the columnar protrusions is embedded in the corresponding second columnar groove, a second polyester film layer is bonded to the lower surface of the second metal plate, a polypropylene layer is bonded to the lower surface of the second polyester film layer, a fluorine-containing resin layer is bonded to the lower surface of the polypropylene layer, a plurality of grooves are arranged in an array, the grooves penetrate through the fluorine-containing resin layer, the polypropylene layer, and the second polyester film layer and expose the lower surface of the second metal plate, each of the grooves is embedded with a metal block, the top surface of the metal block is in contact with the lower surface of the second metal plate, and the lower end portion of the metal block is exposed to the fluorine-containing resin layer;
a first thermally conductive encapsulant adhesive layer, wherein the first thermally conductive encapsulant adhesive layer covers the solar cell back plate, the upper end portion of the thermally conductive elastic pillar exposed to the first polyolefin bonding layer is embedded in the first thermally conductive encapsulant adhesive layer;
a second encapsulant adhesive layer, wherein the second encapsulant adhesive layer covers the first thermally conductive encapsulant adhesive layer;
a plurality of silicon-based solar cell sheets provided on the second encapsulant adhesive layer;
a third encapsulant adhesive layer, wherein the third encapsulant adhesive layer covers the silicon-based solar cell sheets; and
a tempered glass plate, wherein the tempered glass plate is provided above the third encapsulant adhesive layer.

2. The silicon-based solar cell panel according to claim 1, wherein the first metal plate and the second metal plate are made of one of aluminum, copper, stainless steel, and aluminum-magnesium alloy, the first polyester film layer has a thickness of 2-4 mm, the polyimide film has a thickness of 1-1.5 mm, and the first polyolefin bonding layer has a thickness of 100-150 μm.

3. The silicon-based solar cell panel according to claim 2, wherein the thermally conductive elastic pillar comprises a metal copper core, a silicone rubber layer is provided on the side surface of the metal copper core, a second polyolefin bonding layer is provided on the surface of the silicone rubber layer, the metal copper core has a diameter of 5-10 mm, the silicone rubber layer has a thickness of 5-10 mm, and the second polyolefin bonding layer has a thickness of 50-100 μm.

4. The silicon-based solar cell panel according to claim 2, wherein the columnar protrusions have a diameter of 2-5 mm, the adjacent columnar protrusions have a pitch of 4-8 mm, the columnar protrusions have a height of 0.4-0.8 mm, the rubber buffer layer has a thickness 300-700 μm, and the portion of the columnar protrusions exposed to the rubber buffer layer has a height of 50-100 μm.

5. The silicon-based solar cell panel according to claim 1, wherein the second polyester film layer has a thickness of 1-3 mm, the polypropylene layer has a thickness of 0.5-1 mm, the fluorine-containing resin layer has a thickness of 100-200 μm, the metal block is made of aluminum or copper, and the lower end portion of the metal block exposed to the fluorine-containing resin layer has a length of 1-2 mm.

6. The silicon-based solar cell panel according to claim 1, wherein the first thermally conductive encapsulant adhesive layer comprises a polyolefin resin and a thermally conductive nanoparticle, the thermally conductive nanoparticle is one of aluminium oxide, aluminum nitride, boron nitride, silicon nitride and magnesium oxide, the thermally conductive nanoparticle has a particle diameter of 100-200 nm, and the second encapsulant adhesive layer and the third encapsulant adhesive layer are made of polyolefin.

7. The silicon-based solar cell panel according to claim 6, wherein the first thermally conductive encapsulant adhesive layer has a thickness of 400-500 μm, the second encapsulant adhesive layer has a thickness of 50-100 μm, the third encapsulant adhesive layer has a thickness of 200-300 μm, and the upper end portion of the thermally conductive elastic pillar embedded in the first thermally conductive encapsulant adhesive layer has a length of 200-400 μm.

8. The silicon-based solar cell panel according to claim 1, wherein the fluorine-containing resin layer is made of polytetrafluoroethylene, polychlorotrifluoroethylene, polyvinylidene fluoride, polyvinyl fluoride, an ethylene-chlorotrifluoroethylene copolymer or an ethylene-tetrafluoroethylene copolymer.
